(19) United States
(12) Patent Application Publication
(10) Pub. No.: US 2007/0296083 A1
(43) Pub. Date: Dec. 27, 2007

(54) Low dielectric constant integrated circuit insulators and methods

(75) Inventor: Paul A. Farrar, Bluffton, SC (US)

Correspondence Address: SCHWEGMAN, LUNDBERG & WOESSNER, P.A., P.O. BOX 2938, MINNEAPOLIS, MN, 55402, US

(73) Assignee: Micron Technology, Inc.

(21) Appl. No.: 11/471,855

(22) Filed: Jun. 21, 2006

(51) Int. Cl. H01L 23/52; H01L 21/4763

(52) U.S. Cl. 257/751; 438/678; 438/643; 438/645; 257/762

(57) ABSTRACT

A system for low dielectric constant insulators is provided. One aspect of this disclosure relates to a method for forming an insulator. According to an embodiment of the method, a first structural material is applied as one or more layers of insulation to an integrated circuit surface, a damascene pattern is etched into the first structural material, a first barrier layer and a seed layer are deposited upon the insulation layer, a conductor layer is deposited upon the seed layer, at least a portion of the conductor layer is planarized and at least a portion of the first structural material is removed, a top barrier layer is deposited upon the conductor layer, and a final structural material is applied to replace at least a portion of the first structural material, the final structural material having a lower dielectric constant than the first structural material. Other aspects and embodiments are provided.

### CROSS REFERENCE TO RELATED APPLICATIONS

This application is related to the following commonly assigned U.S. patent application which is herein incorporated by reference in its entirety: “Integrated Circuit Insulators and Related Methods,” U.S. application Ser. No. 11/275,085, filed on Dec. 8, 2005.

### TECHNICAL FIELD

This disclosure relates to semiconductor devices and semiconductor device fabrication, and more particularly, to low dielectric constant integrated circuit insulators and methods.

### BACKGROUND

Advances in the field of semiconductor manufacturing have decreased the achievable minimum feature size. This decrease in feature size has the undesirable side effect of increasing the capacitive coupling between adjacent devices. As the amount of interconnecting metallurgy increases, the capacitive coupling problem impedes performance. Efforts to minimize the effects of capacitive coupling include isolating wiring into levels with insulators or air gaps between the levels.

Silicon dioxide is a commonly used insulator in the fabrication of integrated circuits. As the density of devices, such as resistors, capacitors and transistors, in an integrated circuit is increased, several problems related to the use of silicon dioxide insulators arise. First, as metal signal carrying lines are packed more tightly, the capacitive coupling between the lines is increased. This increase in capacitive coupling is a significant impediment to achieving high speed information transfer between and among the integrated circuit devices. Silicon dioxide contributes to this increase in capacitive coupling through its dielectric constant, which has a relatively high value of four. Second, as the cross-sectional area of the signal carrying lines is decreased for the purpose of increasing the packing density of the devices that comprise the integrated circuit, the signal carrying lines become more susceptible to fracturing induced by a mismatch between the coefficients of thermal expansion of the silicon dioxide and the signal carrying lines.

One solution to the problem of increased capacitive coupling between signal carrying lines is to use an insulating material that has a lower dielectric constant than silicon dioxide. Polyimide has a dielectric constant of between about 2.8 and 3.5, which is lower than the dielectric constant of silicon dioxide. Using polyimide lowers the capacitive coupling between the signal carrying lines. Unfortunately, there are limits to the extendibility of this solution, since there are a limited number of insulators that have a lower dielectric constant than silicon dioxide and are compatible with integrated circuit manufacturing processes.

One solution to the thermal expansion problem is to use a foamed polymer for the insulating layer. Although the mismatch between the thermal expansion coefficients of foamed polymer and copper may not be less than the mismatch between silicon dioxide and copper, the very low effective yield strength of the foamed polymer means that the stress caused by the mismatch will result in compression of the polymer instead of a rupture of copper signal lines, as has been found in the case of copper-silicon dioxide structures. Although these foamed polymers have low dielectric constants, they also have mechanical properties that are not suitable for certain steps of the semiconductor manufacturing process, such as planarizing. One type of planarizing is chemical-mechanical polishing (CMP). CMP requires that the insulating layer have sufficient mechanical strength to withstand the polishing forces.

Copper, because of its lower resistivity, is rapidly replacing aluminum metallurgy in high performance integrated circuits, while silver is attractive because of its even lower resistivity and gold because of its higher electromigration resistance. However, problems of electromigration and stress migration with copper have created reliability issues as circuit dimensions decrease and current densities increase. In addition, copper, gold and silver conductor material tends to diffuse into insulators and silicon at elevated temperatures either during deposition and subsequent annealing or during circuit operation. To mitigate this problem, a liner is sometimes used to separate the copper, silver, or gold from the insulator. Materials used as diffusion barriers generally have different mechanical hardness as well as higher resistivity than the base conductor and therefore present difficulties in the CMP process.

### BRIEF DESCRIPTION OF THE DRAWINGS

FIGS. 1A-1B illustrate flow diagrams of methods for providing low dielectric insulators in integrated circuits, according to various embodiments.

FIGS. 2A-2F illustrate a method of forming low dielectric insulators in integrated circuits and resulting circuit structure, according to various embodiments of the present subject matter.

FIG. 3 illustrates a wafer, upon which wiring structures with a barrier layer and replaced insulators can be fabricated according to embodiments of the present subject matter.

FIG. 4 illustrates a simplified block diagram of a high-level organization of an electronic system that includes wiring structures with a barrier layer and replaced insulators, according to various embodiments.

FIG. 5 illustrates a simplified block diagram of a high-level organization of an electronic system that includes wiring structures with a barrier layer and replaced insulators, according to various embodiments.

### DETAILED DESCRIPTION

The following detailed description refers to the accompanying drawings which show, by way of illustration, specific aspects and embodiments in which the present invention may be practiced. The various embodiments are not necessarily mutually exclusive, as aspects of one embodiment can be combined with aspects of another embodiment. Other embodiments may be utilized and structural, logical, and electrical changes may be made without departing from the scope of the present invention. In the following description, the terms “wafer” and “substrate” are used interchangeably to refer generally to any structure on which integrated circuits are formed, and also to such structures during various stages of integrated circuit fabrication. Both terms include doped and undoped semiconductors, epitaxial layers of a semiconductor on a supporting semiconductor or insulating material, combinations of such layers, as well as other such structures that are known in the art. The terms “horizontal” and “vertical”, as well as prepositions such as “on”, “over” and “under” are used in relation to the conventional plane or surface of a wafer or substrate, regardless of the orientation of the wafer or substrate. References to “an”, “one”, or “various” embodiments in this disclosure are not necessarily to the same embodiment, and such references contemplate more than one embodiment. The following detailed description is, therefore, not to be taken in a limiting sense, and the scope of the present invention is defined only by the appended claims, along with the full scope of equivalents to which such claims are entitled.

### Integrated Circuit Insulators

Silicon dioxide is a commonly-used insulator in the fabrication of integrated circuits. As the density of devices, such as resistors, capacitors and transistors, in an integrated circuit is increased, several problems related to the use of silicon dioxide insulators arise. First, as metal signal carrying lines are packed more tightly, the capacitive coupling between the lines is increased. This increase in capacitive coupling is a significant impediment to achieving high speed information transfer between and among the integrated circuit devices. Silicon dioxide contributes to this increase in capacitive coupling through its dielectric constant, which has a relatively high value of four. Second, as the cross-sectional area of the signal carrying lines is decreased for the purpose of increasing the packing density of the devices that comprise the integrated circuit, the signal carrying lines become more susceptible to fracturing induced by a mismatch between the coefficients of thermal expansion of the silicon dioxide and the signal carrying lines.

A solution to the problem of increased capacitive coupling between signal carrying lines is to use an insulating material that has a lower dielectric constant than silicon dioxide. Polyimides have a dielectric constant of between about 2.8 and 3.5, which is lower than the dielectric constant of silicon dioxide, while foamed polymers or other foamed materials will have an even lower dielectric constant than the materials from which they are made. Using polyimides, or other low dielectric materials, lowers the capacitive coupling between the signal carrying lines. Unfortunately, there are limits to the extendibility of this solution, since there are a limited number of insulators that have a lower dielectric constant than silicon dioxide and are compatible with integrated circuit manufacturing processes.

A solution to the thermal expansion problem is to use a foamed polymer for the insulating layer. Although the mismatch between the thermal expansion coefficients of foamed polymer and copper may not be less than the mismatch between silicon dioxide and copper, the very low effective yield strength of the foamed polymer means that the stress caused by the mismatch will result in compression of the polymer instead of a rupture of copper signal lines, as has been found in the case of copper-silicon dioxide structures. Although these foamed polymers have low dielectric constants, they also have mechanical properties that are not suitable for certain steps of the semiconductor manufacturing process, such as planarizing. One type of planarizing is chemical-mechanical polishing (CMP). CMP is an integrated circuit manufacturing process involving global planarization of metal and dielectric, and has several benefits. It provides high manufacturing yields, allows for smaller critical dimensions without reducing yield, and is capable of reducing defect density. CMP requires that the insulating layer have sufficient mechanical strength to withstand the polishing forces.

The damascene process which is used for copper, silver and gold metallurgy, specifically, involves first etching the desired metal pattern into an insulator layer, then depositing a barrier and seed layer followed by a layer of metal over the wafer surface. The metal is then polished using CMP to remove the unwanted metal. As stated, CMP requires an insulating material with sufficient mechanical strength to withstand polishing forces. We thus have a situation where the electrical requirements dictate the use of a relatively weak material while the processing requirements dictate the use of a relatively strong material.

Copper, gold or silver conductors are used increasingly of late, as they have lower resistivity and higher electromigration resistance than aluminum conductors. However, even with this improved electromigration resistance, problems of electromigration and stress migration with copper, gold and silver have created reliability issues as circuit dimensions decrease and current densities increase. In addition, conductor material tends to diffuse into insulators and silicon at elevated temperatures either during deposition and subsequent annealing or during circuit operation. To mitigate this problem, a liner or barrier is generally used to separate the copper, silver, or gold from the insulator. Materials used as diffusion barriers generally have different mechanical hardness than the base conductor and therefore present difficulties in the CMP process.

What is described herein is a method which can be used to form a wiring structure with a very low dielectric constant insulator, and a resulting system with wiring metal that has a barrier layer and that requires CMP and an insulator which does not support CMP. A first, relatively rigid, material is used to fill the space between wiring channels for the damascene process. The first material is later removed, and after a top or capping barrier layer is applied, a second material, with a lower dielectric constant, replaces the first material.

### Methods for Providing Low Dielectric Insulators

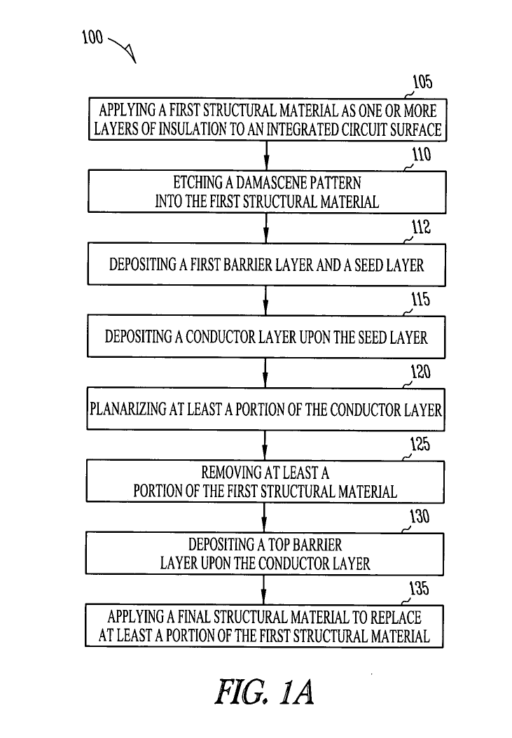

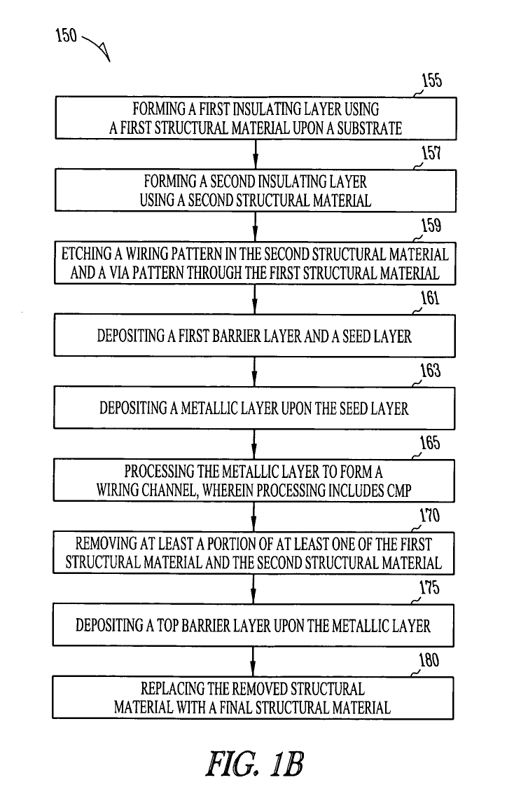

FIGS. 1A-1B illustrate flow diagrams of methods for providing low dielectric insulators in integrated circuits, according to various embodiments. FIG. 1A depicts a method 100 for providing low dielectric constant insulators in integrated circuits. The method includes applying a first structural material as one or more layers of insulation to an integrated circuit surface, at 105. The method also includes etching a pattern into the first structural material, at 110, and depositing a first barrier layer and a seed layer upon the insulation layer, at 112. This method embodiment also includes depositing a conductor layer upon the seed layer, at 115. The method further includes planarizing at least a portion of the conductor layer, at 120, and removing at least a portion of the first structural material, at 125. According to various embodiments, the method includes depositing a top barrier layer upon the conductor layer, at 130, and applying a final structural material to replace at least a portion of the first structural material, the final structural material having a lower dielectric constant than the first structural material, at 135.

Etching a pattern into the first structural material includes etching a damascene pattern, according to an embodiment. According to various embodiments of the method, planarizing at least a portion of the conductor layer includes processing the portion using a chemical-mechanical polishing (CMP) process. Depositing a top barrier layer includes depositing the top barrier layer using an electroless plating process, in an embodiment. The top barrier layer can be constructed of cobalt tungsten phosphide (CoWP), according to one embodiment. According to various embodiments, depositing a top barrier layer includes depositing the top barrier layer using a selective chemical vapor deposition (CVD) process.

According to various embodiments, applying the first barrier layer includes applying Tantalum Nitride (TaN). Physical vapor deposition (PVD), atomic layer deposition (ALD), or other appropriate deposition process is used for the first barrier layer, according to various embodiments. The Tantalum Nitride may be deposited as such or as a TaN—Ta composite layer. CoWP can also be used as the first barrier layer, and can be deposited by PVD, ALD, or a selective process if applied after the conductor is in place and the insulator has been removed. Other materials can be used for the first barrier layer without departing from the scope of the disclosure.

Applying a final insulating material includes applying a polymer, in an embodiment. The method of FIG. 1A may further include exposing the integrated circuit surface to methane radicals to make the surface hydrophobic. According to one embodiment, exposing the integrated circuit surface to methane radicals includes exposing the integrated circuit surface to methane radicals formed using a high frequency electric field.

FIG. 1B depicts a method 150 for forming an integrated circuit insulator. The method includes forming a first insulating layer using a first structural material upon a substrate, the first structural material having sufficient mechanical characteristics to support metal during chemical-mechanical polishing (CMP), at 155, and forming a second insulating layer upon the first insulating layer using a second structural material, at 157. The second structural material has sufficient mechanical characteristics to support metal during CMP, according to various embodiments. The method embodiment also includes etching a wiring pattern in the second structural material and a via pattern through the first structural material, at 159. A first barrier layer and a seed layer are deposited upon the insulating layers, at 161, and a metallic layer is deposited upon the seed layer, at 163. The method further includes processing the metallic layer to form a wiring channel, where the processing includes CMP, at 165, and removing at least a portion of at least one of the first and second structural material, at 170. According to various embodiments, the method also includes depositing a top barrier layer upon the metallic layer, at 175, and replacing the removed structural material with a final structural material, the final structural material having a dielectric constant less than that of the removed structural material, at 180.

According to various embodiments, replacing with a final structural material includes replacing with a foamed polymer. The polymer is foamed using a super critical fluid, such as carbon dioxide, according to an embodiment. According to an embodiment, the foamed polymer has a cell size of not more than 0.1 micron. The first structural material may include Si₃N₄ or SiO₂, or other appropriate insulating material. The second structural material may include Si₃N₄ or SiO₂, or other appropriate insulating material. Depositing a top barrier layer includes electroless plating a layer of CoWP, according to various embodiments. Forming a first insulating layer includes using a dual damascene process, according to various embodiments. While the final structural material can be a foamed polymer, other types of insulating materials, such as an oxide, may be used without departing from the scope of the disclosure.

### Devices and Systems with Low Dielectric Insulators

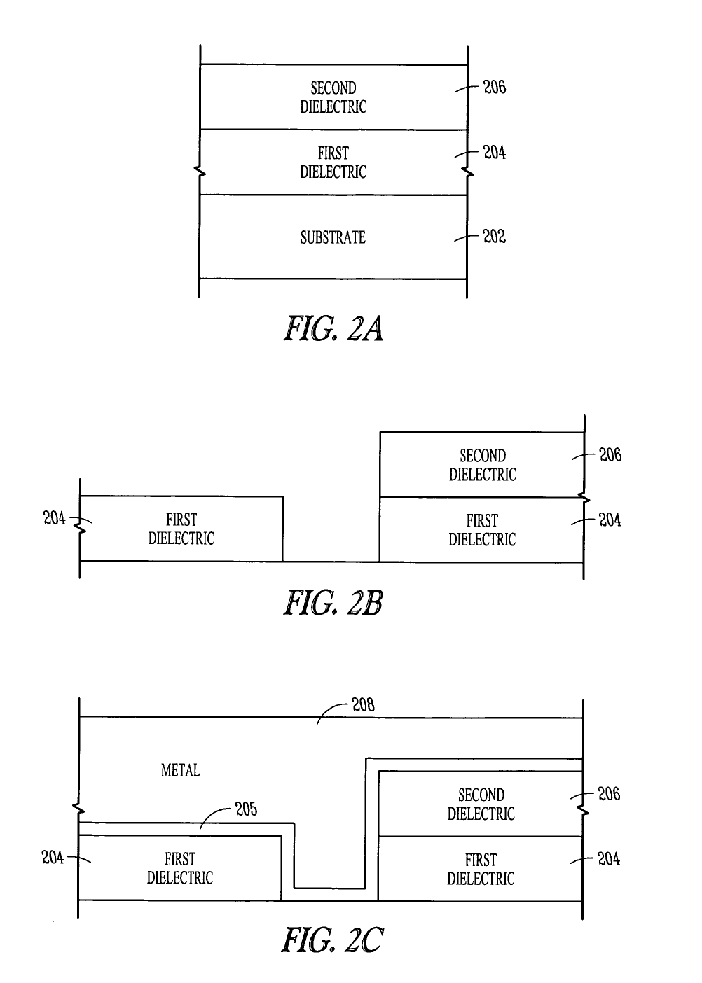

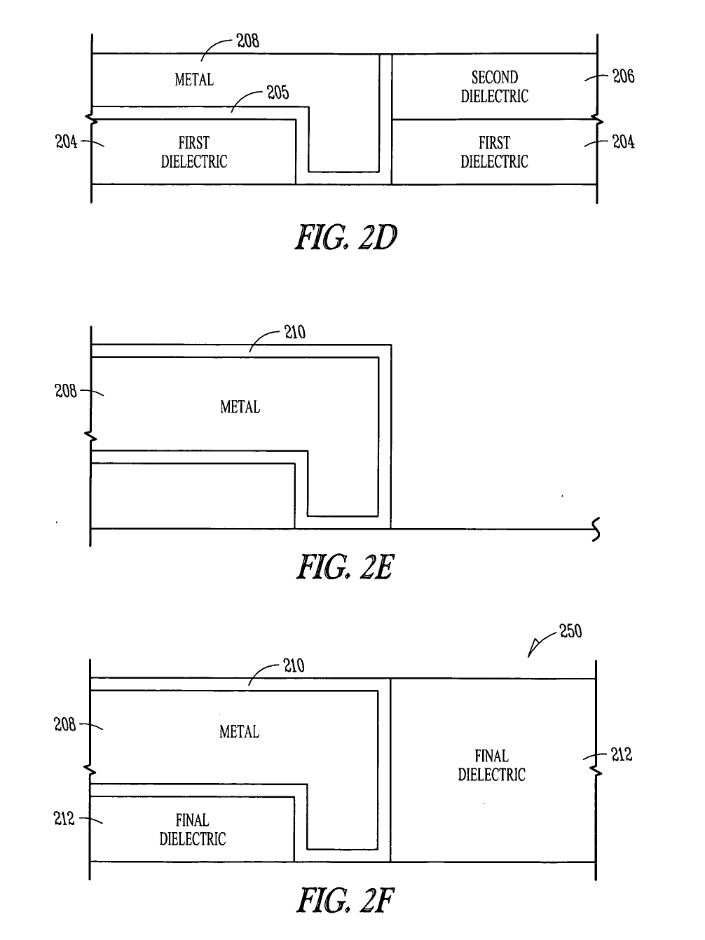

FIGS. 2A-2F illustrate a method of forming low dielectric insulators in integrated circuits and resulting circuit structure, according to various embodiments of the present subject matter. FIG. 2F shows a side view of a simple integrated circuit 250 fabricated as a multi-level system, according to one embodiment of the present invention. FIGS. 2A-2F show process steps to achieve the circuit structure of FIG. 2F.

The device is constructed up to the point where the first metal or conductor level is to be formed. In FIG. 2A, a thickness of a first dielectric 204 equal to the thickness of a first via level has been deposited on a substrate 202, and a thickness of a second insulator, or second dielectric 206, equal to the thickness of the first wiring level has been deposited on the first dielectric 204. In FIG. 2B, a resist layer image has been applied and the pattern of the first metal layer has been etched in the second dielectric 206. A second resist layer has then been applied and the vias have been etched through the first dielectric 204 to the contact level. In FIG. 2C, a first barrier layer 205 has been deposited, and metal layer 208 of copper, gold, silver, or an alloy of copper, gold, or silver has been formed upon a seed layer of copper, gold, silver, or an alloy of copper, gold, or silver. Physical vapor deposition (PVD), atomic layer deposition (ALD), or other appropriate metal deposition process is used for the seed layer, and the remaining metal has been deposited using a standard electrolytic deposition. In FIG. 2D, a planarizing process, such as CMP has been used to remove excess metal, stopping on the second dielectric layer 206. In FIG. 2E, a wet etch has been used to remove the second dielectric and first dielectric, and a top barrier layer 210 has been applied to the top surface of the metal, either using electroless deposit of CoWP, selective CVD, or other deposition process. In FIG. 2F, a final dielectric 212 has been deposited to a thickness of the first conductor level and first via. As discussed, the final dielectric may include a polymer, a foamed polymer, or other dielectric material. Multiple levels of wiring can be formed by repeating the above described process.

When all of the first dielectric layer is removed, an alternate process may be used. In that embodiment, the metal seed and metal layers are deposited prior to planarization. The barrier layers are then applied by a selective process after the first dielectric layer is removed and prior to the deposition of the final dielectric According to one embodiment, the selective process includes selective plating. The selective process includes CVD, according to an embodiment.

According to various embodiments, an integrated circuit structure is formed having wiring structures with a barrier layer and replaced insulators. The structure includes a substrate and a plurality of metal structures planarized into a wiring level while the metal structures are embedded in a first insulator with mechanical properties suitable for a planarizing process, at least a portion of the first insulator providing a sacrificial structure. The structure also includes, in place of the sacrificial structure after the metal structures have been planarized into the wiring level, a barrier layer on at least a portion of the metal structures and a foamed insulator on the substrate. According to various embodiments, the plurality of metal structures may include a plurality of copper, copper alloy, gold, gold alloy, silver or silver alloy structures. Other types of metal conductors may be used without departing from the scope of this disclosure.

According to various embodiments, a conductive system is formed having wiring structures with a barrier layer and replaced insulators. The system includes a substrate and a foamed material layer on the substrate. The system also includes a plurality of conductive metal structures embedded in the foamed material layer, and a barrier layer on at least a portion of the metal structures. According to an embodiment, the foamed material layer has replaced a first insulating layer of higher dielectric constant, and the barrier layer has been deposited, after processing at least a portion of the plurality of metal conductive structures into a wiring level using a chemical-mechanical polishing (CMP) process. In an embodiment, the barrier layer induces CoWP. The foamed material layer includes a type 1 polyimide, in an embodiment. In various embodiments, the foamed material includes polynorbornenes or Avatrel. The foamed material layer can be treated to make the layer hydrophobic, such as by exposing the layer to a methane radical, in an embodiment.

According to various embodiments, a computer system is formed having wiring structures with a barrier layer and replaced insulators. The system includes a processor and a memory system coupled to the processor, where the memory system is on a substrate and comprises a plurality of devices. The system also includes an interconnect system including a plurality of metal structures planarized into a wiring level while the metal structures are embedded in a first insulator with mechanical properties suitable for a planarizing process, at least a portion of the first insulator providing a sacrificial structure. The interconnect system also includes, in place of the sacrificial structure after the metal structures have been planarized into the wiring level, a barrier layer on at least a portion of the metal structures and a foamed insulator on the substrate. According to an embodiment, the first insulator has sufficient mechanical characteristics to support copper conductive structures during CMP. The foamed insulator has insufficient mechanical characteristics to support copper conductive structures during CMP, according to various embodiments. The first insulator has a dielectric constant of at least 4, in an embodiment. The memory system may include at least one RAM cell, at least one ROM cell, at least one DRAM cell, or other desired memory configuration.

The described process involves replacing a temporary insulator (or mandrel) for each level of metallic wiring. The metal is supported from one side during processing. The process can also be implemented by replacing several levels of mandrel material at once. This can be accomplished if the relative length of the longest wire at each level is such that, when the mandrel material is removed, the amount of sag in the wire is less than that which would cause the wires to tangle or become too close when the final insulator layers are added. It has been shown that the maximum unsupported length of wire in an integrated circuit, for most practical applications, is:

L=32Eh²/5p or 1.6(E/p)^{1/4}h^{1/2}

where L is the unsupported length, E is the modulus of elasticity of the metal conductor, p is the density of the wire, and h is the height, or vertical thickness, of the wire.

As the metal and insulator thickness decrease, the maximum allowable sag will also decrease, as will the maximum free span. Design rules are employed to ensure that the maximum distance between two points to be connected by an unsupported wire during processing is within the allowable range. This is achieved in two ways. First, the wiring and unsupported dimensions are determined and an appropriate safety factor for the wire sag is set. Layout rules are then set to constrain the design so that any two points to be connected by unsupported wire are always closer than the maximum distance. Second, a procedure can be developed to place the devices on a chip layout, determine the maximum required unsupported distance and sag safety factor, and then determine the wire and insulator thickness necessary for each level. An alternate method would be to provide intermediate support for longer wires so their use would not necessitate any additional constraints on the layout.

### Wafer Level

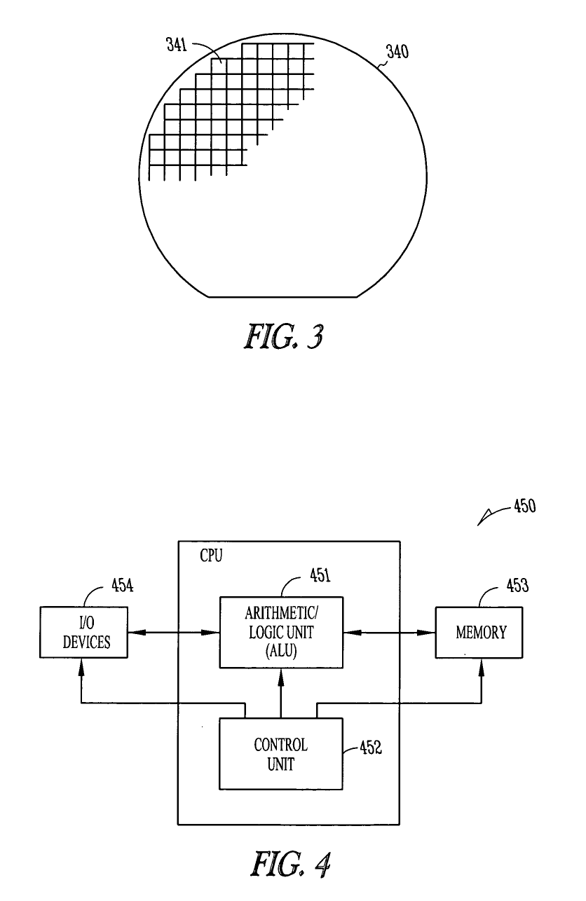

FIG. 3 illustrates a wafer 340, upon which wiring structures with a barrier layer and replaced insulators can be fabricated according to embodiments of the present subject matter. A common wafer size is 8 or 12 inches in diameter. However, wafers are capable of being fabricated in other sizes, and the present subject matter is not limited to wafers of a particular size. A number of dies can be formed on a wafer. A die 341 is an individual pattern, typically rectangular, on a substrate that contains circuitry to perform a specific function. A semiconductor wafer typically contains a repeated pattern of such dies containing the same functionality. A die is typically packaged in a protective casing (not shown) with leads extending therefrom (not shown) providing access to the circuitry of the die for communication and control.

### System Level

FIG. 4 illustrates a simplified block diagram of a high-level organization of an electronic system that includes wiring structures with a barrier layer and replaced insulators, according to various embodiments. In various embodiments, the system 450 is a computer system, a process control system or other system that employs a processor and associated memory. The electronic system 450 has functional elements, including a processor or arithmetic/logic unit (ALU) 451, a control unit 452, a memory device unit 453 and an input/output (I/O) device or devices 454. Generally such an electronic system 450 will have a native set of instructions that specify operations to be performed on data by the processor 451 and other interactions between the processor 451, the memory device unit 453 and the I/O devices 454. The control unit 452 coordinates all operations of the processor 451, the memory device 453 and the I/O devices 454 by continuously cycling through a set of operations that cause instructions to be fetched from the memory device 453 and executed. According to various embodiments, the memory device 453 includes, but is not limited to, random access memory (RAM) devices, read-only memory (ROM) devices, and peripheral devices such as a floppy disk drive and a compact disk CD-ROM drive. As one of ordinary skill in the art will understand upon reading and comprehending this disclosure, any of the illustrated electrical components are capable of being fabricated to include wiring structures with a barrier layer and replaced insulators in accordance with the present subject matter.

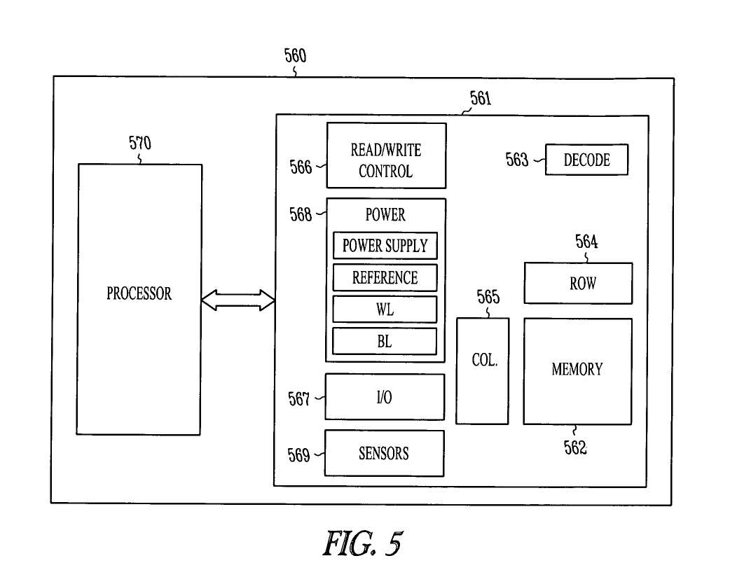

FIG. 5 illustrates a simplified block diagram of a high-level organization of an electronic system that includes wiring structures with a barrier layer and replaced insulators, according to various embodiments. The system 560 includes a memory device 561 which has an array of memory cells 562, address decoder 563, row access circuitry 564, column access circuitry 565, read/write control circuitry 566 for controlling operations, and input/output circuitry 567. The memory device 561 further includes power circuitry 568, and sensors 569 for determining the state of the memory cells. The illustrated power circuitry 568 includes power supply circuitry, circuitry for providing a reference voltage, circuitry for providing the word line with pulses, and circuitry for providing the bit line with pulses. Also, as shown in FIG. 5, the system 560 includes a processor 570, or memory controller for memory accessing. The memory device receives control signals from the processor over wiring or metallization lines. The memory device is used to store data which is accessed via I/O lines. It will be appreciated by those skilled in the art that additional circuitry and control signals can be provided, and that the memory device has been simplified. At least one of the processor or memory device includes the wiring structures with a barrier layer and replaced insulators according to the present subject matter.

The illustration of system 560, as shown in FIG. 5, is intended to provide a general understanding of one application for the structure and circuitry of the present subject matter, and is not intended to serve as a complete description of all the elements and features of an electronic system. As one of ordinary skill in the art will understand, such an electronic system can be fabricated in single-package processing units, or even on a single semiconductor chip, in order to reduce the communication time between the processor and the memory device.

Applications containing wiring structures with a barrier layer and replaced insulators, as described in this disclosure, include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

This disclosure includes several processes, circuit diagrams, and structures. The present invention is not limited to a particular process order or logical arrangement. Although specific embodiments have been illustrated and described herein, it will be appreciated by those of ordinary skill in the art that any arrangement which is calculated to achieve the same purpose may be substituted for the specific embodiments shown. This application is intended to cover adaptations or variations. It is to be understood that the above description is intended to be illustrative, and not restrictive. Combinations of the above embodiments, and other embodiments, will be apparent to those of skill in the art upon reviewing the above description. The scope of the present invention should be determined with reference to the appended claims, along with the full scope of equivalents to which such claims are entitled.

What is claimed is:

1. A method, comprising:
applying a first structural material as one or more layers of insulation to an integrated circuit surface;
etching a damascene pattern into the first structural material;
depositing a first barrier layer and a seed layer upon the insulation layer;
depositing a conductor layer upon the seed layer;
planarizing at least a portion of the conductor layer;
removing at least a portion of the first structural material;
depositing a top barrier layer upon the conductor layer; and
applying a final structural material to replace at least a portion of the first structural material, the final structural material having a lower dielectric constant than the first structural material.

2. The method of claim 1, wherein planarizing at least a portion of the conductor layer includes processing the portion using a chemical-mechanical polishing (CMP) process.

3. The method of claim 1, wherein depositing a top barrier layer includes depositing the top barrier layer using an electroless plating process.

4. The method of claim 3, wherein deposing a top barrier layer includes depositing cobalt tungsten phosphide (CoWP).

5. The method of claim 1, wherein depositing a top barrier layer includes depositing the top barrier layer using a selective chemical vapor deposition (CVD) process.

6. The method of claim 1, wherein applying a final insulating material includes applying a polymer.

7. The method of claim 6, further comprising:
exposing the integrated circuit surface to methane radicals.

8. The method of claim 7, wherein exposing the integrated circuit surface to methane radicals includes exposing the integrated circuit surface to methane radicals formed using a high frequency electric field.

9. A method, comprising:
forming an insulating layer using a first structural material upon a substrate, the first structural material having sufficient mechanical characteristics to support metal during chemical-mechanical polishing (CMP);
forming a second insulating layer of a second structural material upon the first structural material;
etching a wiring pattern into the second structural material and a via pattern through the first structural material;
depositing a first barrier layer and a seed layer upon the insulating layers;
depositing a metallic layer upon the seed layer;
processing the metallic layer to form a wiring channel, wherein processing includes CMP;
removing at least a portion of at least one of the first and second structural material;
depositing a top barrier layer upon the metallic layer; and
replacing the removed structural material with a final structural material, the final structural material having a dielectric constant less than a dielectric constant of the removed structural material.

10. The method of claim 9, wherein replacing with a final structural material includes replacing with a foamed polymer.

11. The method of claim 10, wherein replacing with a foamed polymer includes replacing with a polymer that is foamed using a super critical fluid.

12. The method of claim 11, wherein replacing with a foamed polymer includes replacing with a polymer that is foamed using carbon dioxide.

13. The method of claim 10, wherein replacing with a foamed polymer includes replacing with a foamed polymer having a cell size of not more than 0.1 micron.

14. The method of claim 9, wherein forming a first insulating layer using a first structural material includes forming the first insulating layer using Si₃N_{4.}

15. The method of claim 9, wherein depositing a top barrier layer includes electroless plating a layer of cobalt tungsten phosphide (CoWP).

16. The method of claim 9, wherein forming a first insulating layer includes using a dual damascene process.

17. The method of claim 9, wherein replacing with a final structural material includes replacing with an oxide.

18. An integrated circuit structure, comprising:
a substrate;
a plurality of metal structures planarized into a wiring level while the metal structures are embedded in a first insulator with mechanical properties suitable for a planarizing process, at least a portion of the first insulator providing a sacrificial structure; and
in place of the sacrificial structure after the metal structures have been planarized into the wiring level, a barrier layer on at least a portion of the metal structures and a foamed insulator on the substrate.

19. The integrated circuit structure of claim 18, wherein the plurality of metal structures include a plurality of copper structures.

20. The integrated circuit structure of claim 18, wherein the plurality of metal structures include a plurality of copper alloy structures.

21. The integrated circuit structure of claim 18, wherein the plurality of metal structures include a plurality of gold structures.

22. The integrated circuit structure of claim 18, wherein the plurality of metal structures include a plurality of gold alloy structures.

23. The integrated circuit structure of claim 18, wherein the plurality of metal structures include a plurality of silver structures.

24. The integrated circuit structure of claim 18, wherein the plurality of metal structures include a plurality of silver alloy structures.

25. A conductive system, comprising:
a substrate;
a foamed material layer on the substrate;
a plurality of conductive metal structures embedded in the foamed material layer; and
a barrier layer on at least a portion of the metal structures;
wherein the foamed material layer has replaced a first insulating layer of higher dielectric constant and the barrier layer has been deposited after processing at least a portion of the plurality of metal conductive structures into a wiring level using a chemical-mechanical polishing (CMP) process.

26. The conductive system of claim 25, wherein the barrier layer induces cobalt tungsten phosphide (CoWP).

27. The conductive system of claim 25, wherein the foamed material layer includes a type 1 polyimide.

28. The conductive system of claim 25, wherein the foamed material layer includes polynorbornenes.

29. The conductive system of claim 28, wherein the polynorbornenes include Avatrel.

30. The conductive system of claim 25, wherein the foamed material layer has been treated to make the layer hydrophobic.

31. The conductive system of claim 30, wherein the foamed material layer has been treated with a methane radical to make the layer hydrophobic.

32. A computer system, comprising:
a processor;
a memory system coupled to the processor, wherein the memory system is on a substrate and comprises a plurality of devices; and
an interconnect system comprising:
a plurality of metal structures planarized into a wiring level while the metal structures are embedded in a first insulator with mechanical properties suitable for a planarizing process, at least a portion of the first insulator providing a sacrificial structure; and
in place of the sacrificial structure after the metal structures have been planarized into the wiring level, a barrier layer on at least a portion of the metal structures and a foamed insulator on the substrate.

33. The computer system of claim 32, wherein the first insulator has sufficient mechanical characteristics to support copper conductive structures during chemical-mechanical polishing (CMP).

34. The computer system of claim 32, wherein the foamed insulator has insufficient mechanical characteristics to support copper conductive structures during chemical-mechanical polishing (CMP).

35. The computer system of claim 32, wherein the first insulator has a dielectric constant of at least 4.

36. The computer system of claim 32, wherein the memory system includes at least one RAM cell.

37. The computer system of claim 32, wherein the memory system includes at least one ROM cell.

38. The computer system of claim 36, wherein the memory system includes at least one DRAM cell.

39. A method, comprising:
applying a first structural material as one or more layers of insulation to an integrated circuit surface;
etching a pattern into the first structural material;
forming a conductor layer upon the first structural material;
planarizing at least a portion of the conductor layer;
removing the first structural material;
depositing a top barrier layer upon the conductor layer using a selective process; and
applying a final structural material to replace the first structural material.

40. The method of claim 39, wherein depositing a top barrier layer includes depositing the top barrier layer using a selective chemical vapor deposition (CVD) process.

41. The method of claim 39, wherein depositing a top barrier layer includes depositing the top barrier layer using a selective electroless plating process.
